(19) United States
(12) Patent Application Publication
(10) Pub. No.: US 2025/0212376 A1
(43) Pub. Date: Jun. 26, 2025

(54) COMPONENT CONFIRMATION DEVICE

(71) Applicant: FUJI CORPORATION, Chiryu (JP)

(72) Inventor: Mizuho NOZAWA, Kota-cho (JP)

(73) Assignee: FUJI CORPORATION, Chiryu (JP)

(21) Appl. No.: 18/848,327

(22) PCT Filed: Apr. 25, 2022
(86) PCT No.: PCT/JP2022/018773

§ 371 Date: Sep. 18, 2024

(51) Int. Cl. H05K 13/08; B65H 19/10; G06T 7/00; H05K 13/02

(52) U.S. Cl. CPC H05K 13/082; B65H 19/10; G06T 7/0004; H05K 13/021; G06T 2207/30164

(57) ABSTRACT

A component confirmation device includes a kitting device and a confirmation section. The kitting device sets a reel, on which a carrier tape accommodating a component is wound, on a feeder. The confirmation section confirms suitability of the component in the kitting device based on component features of the component accommodated in the carrier tape of the reel set on the feeder.

### TECHNICAL FIELD

The present description discloses a technology related to a component confirmation device.

### BACKGROUND ART

In the off-line setup device for electronic components described in Patent Literature 1, a feeder is set in a feeder cart according to a production model, or a feeding tape having electronic components is set in the feeder already set in the feeder cart. Further, the off-line setup device for electronic components includes off-line setup data, a reading means, and a replacement-error prevention control means. The off-line setup data includes, according to the production model, at least one of feeder information to be set in the feeder cart and electronic component information of the electronic components. The reading means reads correspondence data corresponding to the off-line setup data from a target to be set. The replacement-error prevention control means prevents an error in replacement of a target to be set based on the off-line setup data and the correspondence data.

The component mounting system described in Patent Literature 2 has a function of mounting components on a board, and includes a component mounting line, a host computer, an off-line setup device, and a communication network. The component mounting line includes a printing device and multiple component mounters, which are disposed to be linked up to each other in a conveyance direction of the board. The host computer comprehensively controls the component mounting line and the off-line setup device. The off-line setup device performs the setup change work required for switching a model of the board produced in the component mounting line, outside the component mounting line. The communication network communicably connects the component mounting line, the host computer, and the off-line setup device.

### PATENT LITERATURE

Patent Literature 1: JP-A-2011-108909

Patent Literature 2: JP-A-2017-005075

### SUMMARY OF THE INVENTION

### Technical Problem

In a kitting operation of setting a reel on a feeder, it is necessary to set an appropriate reel on the feeder. In order to confirm that an appropriate reel is set on the feeder, for example, it is assumed that an identification code provided in the feeder and an identification code provided in the reel are read by a code reader, and identification information of the feeder and identification information of the reel are compared.

In this case, for example, a worker needs to read the identification code of the reel to be set on the feeder, but may erroneously read the identification code of the reel, which is detached from the feeder. Further, when the worker attaches the identification code to the reel after the delivery of the reel, there is a possibility of attaching the wrong identification code. Further, there is a possibility that errors in reel manufacturing may occur, such as lot defects where the components accommodated in the reel differ from the components to be accommodated.

In view of such circumstances, the present description discloses a component confirmation device capable of confirming the suitability of a component in a kitting device that sets a reel on a feeder.

### Solution to Problem

The present description discloses a component confirmation device including a kitting device and a confirmation section. The kitting device is configured to set a reel, on which a carrier tape accommodating a component is wound, on a feeder. The confirmation section is configured to confirm suitability of the component in the kitting device based on component features of the component accommodated in the carrier tape of the reel set on the feeder.

### Advantageous Effect of the Invention

With the component confirmation device described above, it is possible to confirm the suitability of component in a kitting device based on component features of the component accommodated in a carrier tape of a reel set on a feeder.

### BRIEF DESCRIPTION OF DRAWINGS

FIG. 1 is a perspective view illustrating an example of a setup device.

FIG. 2 is a plan view of the setup device in FIG. 1.

FIG. 3 is a perspective view illustrating an example of a feeder provided in a feeder holding section.

FIG. 4 is a plan view illustrating an example of a carrier tape.

FIG. 5 is a cross-sectional view of the carrier tape in FIG. 4.

FIG. 6 is a flowchart illustrating an example of a control procedure by the setup device.

FIG. 7 is a configuration diagram illustrating an example of a component confirmation device.

FIG. 8 is a diagram of a part of the setup device in FIG. 2, illustrating a control example by the component confirmation device.

FIG. 9 is a flowchart illustrating an example of a control procedure by the component confirmation device.

FIG. 10 is a plan view illustrating an example of a feeder unit.

FIG. 11 is a configuration diagram illustrating an example of a production facility.

### DESCRIPTION OF EMBODIMENTS

### 1. Embodiment

### 1-1. Configuration Example of Setup Device 10a

Kitting device 10 sets reel 70, on which carrier tape 72 accommodating component 91 is wound, on feeder 60. Kitting device 10 need only set reel 70 on feeder 60, and may take various configurations. For example, kitting device 10 may be setup device 10a or feeder unit 10b.

Setup device 10a automatically sets reel 70 on feeder 60 so that component 91 can be supplied from feeder 60. In feeder unit 10b, reel 70 is set on feeder 60 by a worker. Setup device 10a and feeder unit 10b may take various configurations.

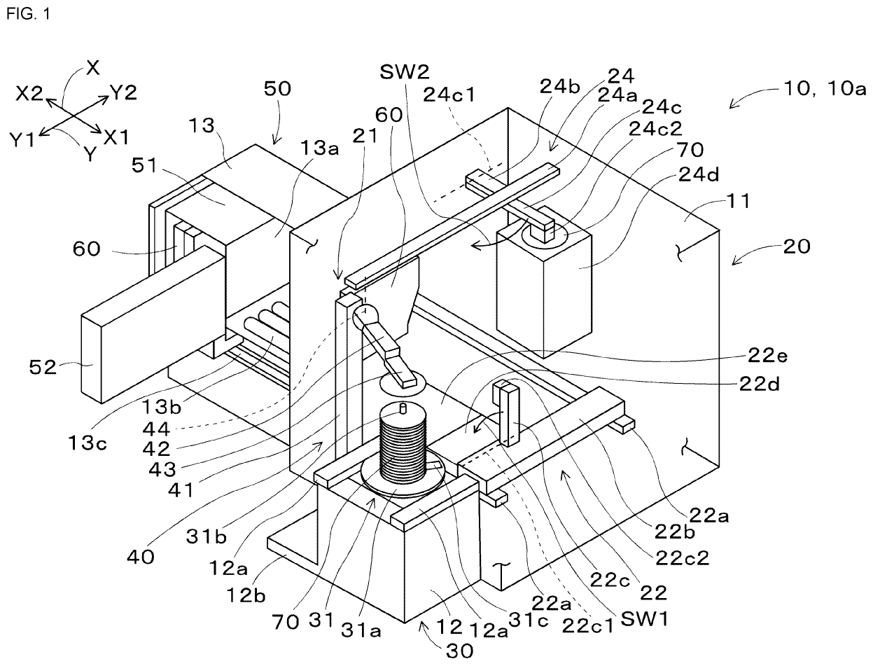

As illustrated in FIGS. 1 to 3, setup device 10a of an embodiment includes reel attachment/detachment section 20, reel supply section 30, reel transfer mechanism 40, and feeder supply section 50. For convenience of description, in the drawings, a facing direction of feeder 60 and reel 70 when reel 70 is attached to and detached from feeder 60 is referred to as a first direction (arrow X direction). In the first direction (arrow X direction), a direction (side) from feeder 60 toward reel 70 is referred to as a first end side (arrow X1 direction) in the first direction, and a direction (side) from reel 70 toward feeder 60 is referred to as a second end side (arrow X2 direction) in the first direction.

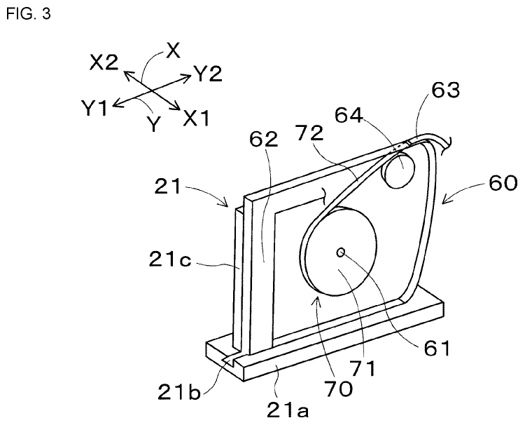

Further, as illustrated in FIG. 3, a sliding direction of feeder 60 in slot 21b, which is a direction orthogonal to the first direction (arrow X direction) in a horizontal plane, is referred to as a second direction (arrow Y direction). In the second direction (arrow Y direction), a sliding direction (side) when feeder 60 is detached is referred to as a first end side (arrow Y1 direction) in the second direction, and a sliding direction (side) when feeder 60 is attached is referred to as a second end side (arrow Y2 direction) in the second direction.

In reel attachment/detachment section 20, various members are assembled inside first housing 11. First housing 11 is a case having a rectangular parallelepiped shape, and a second end side (arrow X2 direction) in the first direction and a first end side (arrow Y1 direction) in the second direction are partially opened. Reel supply section 30 is provided to be coupled to a first end side (arrow Y1 direction) in the second direction of reel attachment/detachment section 20. Reel supply section 30 is formed in box-shaped base 12 smaller than first housing 11. Reel transfer mechanism 40 is provided on plate seat 12b extending from a bottom portion of base 12 to a second end side (arrow X2 direction) in the first direction. Feeder supply section 50 is provided to be coupled to a second end side (arrow X2 direction) in the first direction of reel attachment/detachment section 20. In feeder supply section 50, various members are assembled inside second housing 13 which is smaller than first housing 11 and has storage space 13a in an upper portion.

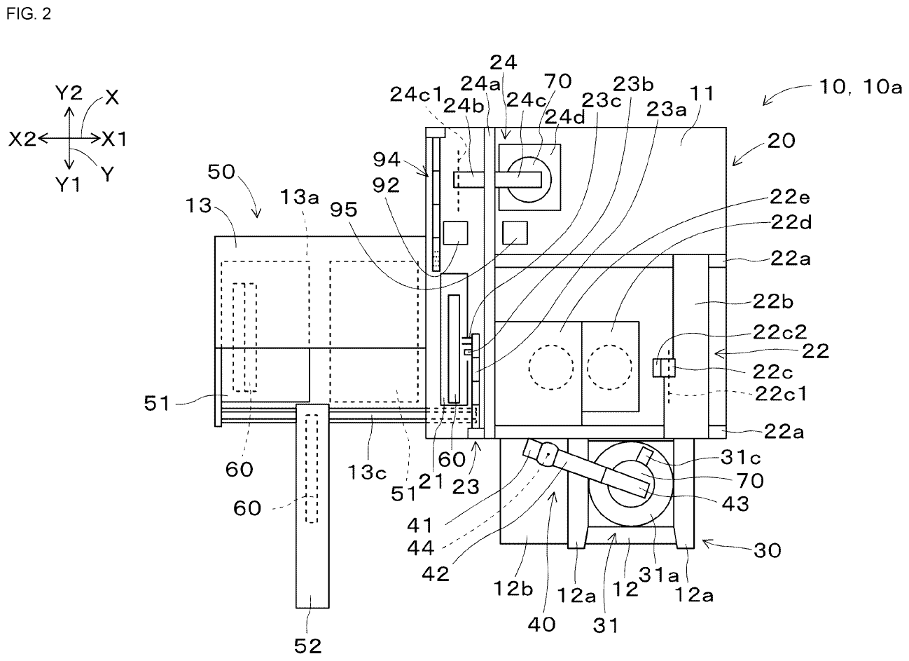

Reel attachment/detachment section 20 includes feeder holding section 21, reel attachment mechanism 22, tape loading mechanism 23, and reel detachment mechanism 24. As illustrated in FIG. 2, feeder holding section 21 is disposed on the second end side (arrow X2 direction) in the first direction and the first end side (arrow Y1 direction) in the second direction inside first housing 11. Feeder holding section 21 holds feeder 60 at a work execution position in a vertical posture. As illustrated in FIG. 3, feeder holding section 21 includes bottom plate 21a, slot 21b, and support plate 21c. Slot 21b is formed in a groove shape extending along the second direction (arrow Y direction) in bottom plate 21a. Feeder 60 is inserted from a first end side (arrow Y1 direction) in the second direction of slot 21b toward a second end side (arrow Y2 direction) in the second direction thereof, and is held at the work execution position. Support plate 21c is provided to stand up from bottom plate 21a, and comes into contact with the side surface of feeder 60 at the work execution position on a second end side (arrow X2 direction) in the first direction. Support plate 21c supports a pressing load to the second end side (arrow X2 direction) in the first direction generated when reel 70 is attached to feeder 60.

Feeder 60 is detachably provided on a component mounter. As illustrated in FIG. 3, in feeder 60, reel 70, on which carrier tape 72 is wound, is attached to main body portion 71, and carrier tape 72 is conveyed to supply component 91. An identification code for identifying reel 70 is given to each reel 70. Feeder 60 is formed in a flat box shape. Feeder 60 includes reel holding shaft 61 that protrudes from a side plate at the second end side (arrow X2 direction) in the first direction toward the first end side (arrow X1 direction) in the first direction at a substantially central position as viewed in the first direction (arrow X direction). Reel holding shaft 61 is inserted into a center hole formed at the center of reel 70, and detachably and rotatably holds reel 70.

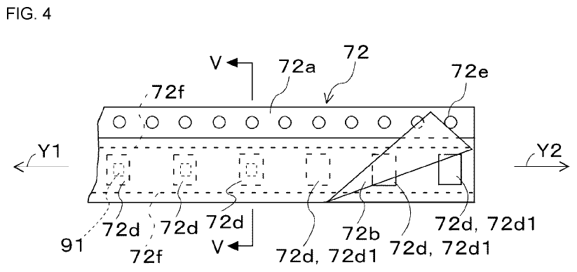

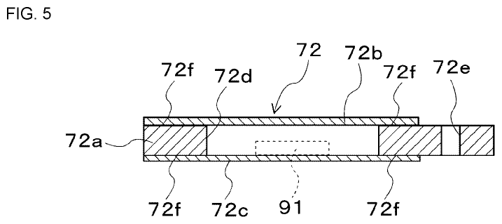

As illustrated in FIGS. 4 and 5, carrier tape 72 includes base tape 72a, cover tape 72b, and bottom tape 72c. Base tape 72a is a base portion of carrier tape 72, and is provided with multiple accommodation sections 72d and multiple feed holes 72e. Component 91 is accommodated in each of multiple accommodation sections 72d. As illustrated in FIG. 4, a predetermined number (for example, three in FIG. 4) of accommodation sections 72d from a tip end side of carrier tape 72 are empty accommodation sections 72d1 in which component 91 is not accommodated. Multiple accommodation sections 72d are provided at predetermined pitch intervals in a longitudinal direction of carrier tape 72 at the center portion in a width direction of base tape 72a.

Each of multiple feed holes 72e is a through hole, and is used when carrier tape 72 is conveyed in the conveyance direction (the second end side (arrow Y2 direction) in the second direction). Multiple feed holes 72e are provided at a predetermined pitch interval in the longitudinal direction of carrier tape 72 on a first end side in the width direction of base tape 72a. Cover tape 72b closes accommodation sections 72d of base tape 72a. Cover tape 72b is attached to the upper surfaces of both end portions of base tape 72a in the width direction by, for example, adhesive 72f or thermocompression bonding. Bottom tape 72c is attached to the lower surface of base tape 72a by, for example, adhesive 72f or thermocompression bonding, and prevents component 91 accommodated in accommodation section 72d from falling off.

A central portion of side plate 62 on a first end side (arrow X1 direction) in the first direction of feeder 60 is open in order to facilitate attachment and detachment of reel 70. At least one of the material of carrier tape 72, the width dimension of carrier tape 72, the width dimension of reel 70, and the diameter dimension of reel 70 is different among multiple types of reels 70, and there are multiple types of feeders 60 corresponding to multiple types of reels 70. Feeder 60 includes collection position 63, sprocket 64, and a tape peeling section.

Collection position 63 is provided on a second end side (arrow Y2 direction) in the second direction of the upper surface of feeder 60, and the component mounter collects component 91 at collection position 63. Sprocket 64 is rotatably provided on a first end side (arrow Y1 direction) in the second direction with respect to collection position 63. A teeth portion of sprocket 64 engage with feed holes 72e of carrier tape 72. Sprocket 64 is intermittently driven by a drive motor and conveys carrier tape 72 at a constant pitch. The tape peeling section can peel off cover tape 72b from base tape 72a immediately before collection position 63 to take out components 91. After passing through collection position 63, carrier tape 72 is cut by a tape cutting device provided in the component mounter.

An identification code for identifying feeder 60 is given to each of feeders 60. Feeder 60 is provided with a feeder control section. The feeder control section stores the identification information of feeder 60 and the identification information of reel 70, and controls the component supply operation. When feeder 60 is held by feeder holding section 21, the connectors are fitted to each other, and the feeder control section is communicably connected to setup device 10a.

Reel attachment mechanism 22 is provided on a first end side (arrow X1 direction) in the first direction of feeder holding section 21. Reel attachment mechanism 22 uses reel transfer mechanism 40 to change reel 70 in a horizontal posture to a vertical posture and attach reel 70 to feeder 60 at the work execution position. Reel attachment mechanism 22 includes pair of guide rails 22a and 22a, moving table 22b, attachment material 22c, placement area 22d, and temporary placement area 22e. In reel attachment mechanism 22, a mechanism that changes reel 70 in the horizontal posture to the vertical posture and a mechanism that attaches reel 70 in the vertical posture to feeder 60 may be separated.

Pair of guide rails 22a and 22a extends along the first direction (arrow X direction) at a substantially central position in the second direction (arrow Y direction) of first housing 11, and is disposed in parallel to be separated from each other. Moving table 22b extends along the second direction (arrow Y direction), and is provided to straddle the upper side of pair of guide rails 22a and 22a. As illustrated in FIGS. 1 and 2, moving table 22b moves along pair of guide rails 22a and 22a, and reciprocates between a standby position provided on the first end side (arrow X1 direction) in the first direction and feeder holding section 21 provided on the second end side (arrow X2 direction) in the first direction.

Attachment material 22c is formed in a square bar shape, and is provided to extend upward from moving table 22b. Attachment material 22c faces reel holding shaft 61 of feeder 60 at the work execution position. Specifically, attachment material 22c is provided at a position separated by a predetermined distance from a tip end portion of reel holding shaft 61 toward the first end side (arrow X1 direction) in the first direction. Attachment material 22c swings (arrow SW1 in FIG. 1) between an upright posture illustrated in FIGS. 1 and 2 and a horizontal posture in which attachment material 22c is tilted toward the second end side (arrow X2 direction) in the first direction around swing shaft 22c1 provided on moving table 22b side. Collection section 22c2 is provided on an end portion different from an end portion of swing shaft 22c1 side of attachment material 22c. Collection section 22c2 detachably collects reel 70. As collection section 22c2, a claw portion inserted into the center hole of reel 70, a gripping mechanism that grips a peripheral edge of reel 70, a pickup mechanism that picks up reel 70 using negative pressure, or the like may be used.

Placement area 22d is provided on the first end side (arrow X1 direction) in the first direction in pair of guide rails 22a and 22a. In placement area 22d, reel 70 to be attached is placed in a horizontal posture. Temporary placement area 22e is provided on pair of guide rails 22a and 22a on the second end side (arrow X2 direction) in the first direction with respect to placement area 22d. In temporary placement area 22e, when reel attachment mechanism 22 changes the use order of reels 70, reels 70 are temporarily placed in the horizontal posture and the use order of reels 70 is changed. In temporary placement area 22e, an area in which multiple reels 70 can be temporarily placed is secured. Moving table 22b and attachment material 22c move above placement area 22d and temporary placement area 22e.

As illustrated in FIG. 2, tape loading mechanism 23 is provided near feeder holding section 21. Tape loading mechanism 23 loads carrier tape 72 in feeder 60 so that carrier tape 72 can be fed. For example, an articulated robot may be used as tape loading mechanism 23. Tape loading mechanism 23 of the embodiment includes articulated arm 23a, camera 23b, and multiple fingers 23c.

Articulated arm 23a can perform operations such as rotation and bending of the arm, and can adjust the positions and directions of camera 23b and multiple fingers 23c. Camera 23b is provided at a tip end portion of articulated arm 23a. Camera 23b images feeder 60 at the work execution position to detect the positions and the states of reel 70 and carrier tape 72. Multiple fingers 23c are provided side by side with camera 23b at the tip end portion of articulated arm 23a. Multiple fingers 23c can perform a moving operation, a twisting operation, and the like in addition to the operation of gripping and releasing a work target.

Multiple fingers 23c loads carrier tape 72 so that feed hole 72e at a tip end portion of carrier tape 72 engages with sprocket 64, and sets carrier tape 72 in a feedable state. Multiple fingers 23c facilitate the loading operation of carrier tape 72 by rotating reel 70 around reel holding shaft 61 as necessary. Tape loading mechanism 23 takes a retracted posture in which articulated arm 23a is bent not to hinder the attaching and detaching operation of reel 70 in a time period other than the operation time.

Reel detachment mechanism 24 is provided on the first end side (arrow X1 direction) in the first direction of feeder holding section 21, and is disposed above reel attachment mechanism 22. Reel detachment mechanism 24 detaches reel 70 from feeder 60 at the work execution position. Reel detachment mechanism 24 includes guide rail 24a, moving table 24b, detachment material 24c, and retrieval box 24d.

Guide rail 24a is provided in the vicinity of the ceiling of first housing 11, and is formed to extend along the second direction (arrow Y direction). Moving table 24b is formed to extend along the first direction (arrow X direction), and is provided below guide rail 24a. As illustrated in FIGS. 1 and 2, moving table 24b moves along guide rail 24a and reciprocates between feeder holding section 21 and a standby position provided on the second end side (arrow Y2 direction) in the second direction.

Detachment material 24c is formed of a thick plate-shaped member longer than moving table 24b, and is provided to extend along the first direction (arrow X direction) below moving table 24b. Detachment material 24c swings (arrow SW2 in FIG. 1) between a horizontal posture illustrated in FIGS. 1 and 2 and a vertical posture in which detachment material 24c is tilted downward around swing shaft 24c1 provided on the second end side (arrow X2 direction) in the first direction of moving table 24b. Collection section 24c2 is provided on an end portion on a side different from the end portion on swing shaft 24c1 side of detachment material 24c. Collection section 24c2 detachably collects reel 70. The collecting method of collection section 24c2 may be the same as or different from collection section 22c2 of reel attachment mechanism 22.

Retrieval box 24d is provided to be positioned below detachment material 24c when moving table 24b is moved to the standby position. Retrieval box 24d retrieves multiple detached reels 70. Retrieval box 24d is formed in a box shape opening upward. Accordingly, retrieval box 24d can retrieve reel 70 that falls when collection section 24c2 of detachment material 24c releases reel 70.

Reel supply section 30 includes reel holding section 31 that is detachably provided. Pair of guide plates 12a and 12a extending along the second direction (arrow Y direction) is provided on the first end side (arrow X1 direction) in the first direction and the second end side (arrow X2 direction) in the first direction of the upper surface of base 12. Reel holding section 31 is placed between pair of guide plates 12a and 12a of base 12. As illustrated in FIG. 2, surfaces of pair of guide plates 12a and 12a facing each other on the first end side (arrow Y1 direction) in the second direction are formed in a tapered shape, and a separation distance on the first end side (arrow Y1 direction) in the second direction is longer than that on the second end side (arrow Y2 direction) in the second direction. This facilitates the work of inserting reel holding section 31 toward base 12 from the first end side (arrow Y1 direction) in the second direction.

Reel holding section 31 stacks and holds multiple reels 70 in a horizontal posture. Reel 70 is not limited to an unused reel, and may be a reel in use in which carrier tape 72 has been used halfway. Reel holding section 31 includes a circular plate-shaped holding plate 31a provided horizontally, and round rod-shaped holding shaft 31b provided upward from the center of holding plate 31a and penetrating through the center hole of reel 70. Accordingly, reel holding section 31 can hold multiple reels 70 in a state where holding shaft 31b penetrates through the center holes of multiple reels 70 even when reels 70 having at least one of different diameter and different width dimension coexist, and reel 70 can be easily taken out. Identification code 31c is given to an upper surface of holding plate 31a. Identification code 31c includes information for specifying reel holding section 31.

For example, the worker procures multiple reels 70 based on work instruction data, and performs a stacking work of stacking multiple reels 70 on reel holding section 31. The work instruction data indicates a work content of the setup work performed by setup device 10a. That is, in the work instruction data, the type information of multiple reels 70 required with the progress of the production of the board product by the component mounter is associated with the type information of multiple feeders 60 applicable to reels 70. A known automated guided vehicle or the like may also be used to convey multiple reels 70.

Reel transfer mechanism 40 is provided on plate seat 12b extending from a bottom portion of base 12 to a second end side (arrow X2 direction) in the first direction. Reel transfer mechanism 40 includes support column 41, arm 42, and collection section 43. Support column 41 stands upward in the vertical direction on the second end side (arrow Y2 direction) in the second direction of plate seat 12b. Arm 42 is provided to be liftable and lowerable with respect to support column 41. Further, arm 42 is provided to be rotatable on a horizontal plane around rotation axis 44 close to support column 41.

Collection section 43 is provided to be extendable and contractible with respect to arm 42. Collection section 43 detachably collects reel 70. The collecting method of collection section 43 may be the same as or different from collection section 22c2 of reel attachment mechanism 22 and collection section 24c2 of reel detachment mechanism 24. Collection section 43 is provided with a code reader. The code reader reads identification code 31c of reel holding section 31. Further, the code reader can read the identification code of uppermost reel 70.

Reel transfer mechanism 40 functions as a part of reel attachment mechanism 22. Specifically, reel transfer mechanism 40 takes out reel 70 from reel holding section 31 by driving arm 42 and collection section 43. Further, reel transfer mechanism 40 places taken out reel 70 in placement area 22d or temporary placement area 22e in the state of the horizontal posture by driving arm 42 and collection section 43. Reel transfer mechanism 40 subsequently uses multiple reels 70 stacked on reel holding section 31 from the uppermost portion.

Feeder supply section 50 includes feeder accommodation section 51 that is detachably provided and feeder conveyance section 52. As illustrated in FIG. 2, storage space 13a in the upper portion of second housing 13 is open on the first end side (arrow Y1 direction) in the second direction, and can store multiple (for example, two in FIG. 2) feeder accommodation sections 51 arranged along the first direction (arrow X direction). As illustrated in FIG. 1, multiple roller conveyors 13b extending along the first direction (arrow X direction) are provided on a bottom surface defining storage space 13a, so that a storage operation of feeder accommodation section 51 is facilitated.

Feeder accommodation section 51 is formed in a box shape whose first end side (arrow Y1 direction) in the second direction is opened. Multiple slots having the same shape as slot 21b of feeder holding section 21 are formed on the bottom surface of feeder accommodation section 51. Feeder accommodation section 51 can accommodate multiple feeders 60 in a vertical posture arranged along the first direction (arrow X direction). When multiple feeders 60 are accommodated in feeder accommodation section 51 and feeder accommodation section 51 is properly stored in storage space 13a, the connectors of feeder 60 and feeder accommodation section 51 are fitted to each other, and multiple feeder control sections are communicably connected to setup device 10a.

An identification code for identifying feeder accommodation section 51 is given to feeder accommodation section 51. For example, the worker procures multiple feeders 60 to be used based on the work instruction data, and performs the accommodation work of accommodating feeders 60 in feeder accommodation section 51. The number of feeder accommodation sections 51 that can be accommodated in storage space 13a may be one or three or more. A known automated guided vehicle or the like can also be used to convey multiple feeders 60.

Guide rail 13c is provided in a lower portion on the first end side (arrow Y1 direction) in the second direction of storage space 13a of second housing 13. Guide rail 13c is provided in storage space 13a over substantially the entire first direction (arrow X direction), and is provided to extend to the first end side (arrow Y1 direction) in the second direction of feeder holding section 21. Guide rail 13c is provided with feeder conveyance section 52. Feeder conveyance section 52 moves along guide rail 13c and reciprocates between feeder accommodation section 51 and feeder holding section 21.

Feeder conveyance section 52 is formed in a box shape having an opening portion on the second end side (arrow Y2 direction) in the second direction. Feeder conveyance section 52 includes a built-in space that temporarily incorporates feeder 60, and a feeder operation mechanism that conveys feeder 60 into built-in space through the opening portion and conveys feeder 60 out of built-in space. Accordingly, feeder conveyance section 52 can convey feeder 60 out of feeder accommodation section 51 and feeder holding section 21, and can convey feeder 60 into feeder accommodation section 51 and feeder holding section 21. An openable and closable safety fence is provided on the first end side (arrow Y1 direction) in the second direction of reel supply section 30 and feeder supply section 50, and the approach of the worker to reel supply section 30 and feeder supply section 50 is suppressed.

### 1-2. Control Example of Setup Device 10a

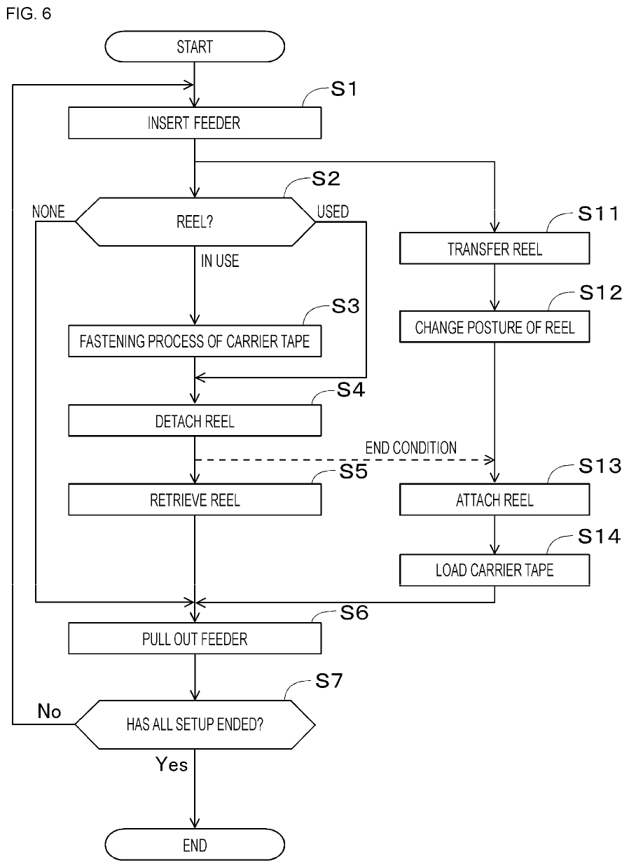

Setup device 10a causes feeder conveyance section 52 to convey feeder 60 corresponding to uppermost reel 70 of reel holding section 31 (step S1 illustrated in FIG. 6). Feeder conveyance section 52 pulls out and incorporates feeder 60 from feeder accommodation section 51, moves to feeder holding section 21, and inserts incorporated feeder 60 into feeder holding section 21. Accordingly, feeder 60 is held at the work execution position, and the identification code of feeder 60 is read.

When there is no feeder 60 applicable to uppermost reel 70 of reel holding section 31, reel 70 is placed in temporary placement area 22e by reel transfer mechanism 40. The above-described placement is repeated until applicable feeder 60 is present, and feeder 60 corresponding to uppermost reel 70 of reel holding section 31 is inserted into feeder holding section 21. After the control illustrated in step S1, in setup device 10a, a first-series control illustrated in steps S2 to S5 and a second-series control illustrated in steps S11 to S14 are executed in parallel.

In the first-series control, setup device 10a confirms the state of reel 70 based on the read identification code of feeder 60 or the read identification code of reel 70, and changes the control according to the state of reel 70 (step S2). Specifically, when feeder 60 is used in the component mounter in advance, there is a possibility that reel 70 in use in which carrier tape 72 has been used halfway is provided in feeder 60. In this case, tape loading mechanism 23 performs a fastening process of fixing the tip end portion of carrier tape 72 with a tape or the like to suppress slack of carrier tape 72 (step S3). In this case, tape loading mechanism 23 can wind carrier tape 72 around reel 70 as necessary. Thereafter, tape loading mechanism 23 takes a retracted posture in which articulated arm 23a is bent.

Next, reel detachment mechanism 24 detaches reel 70 from feeder 60 (step S4). Specifically, moving table 24b moves from the standby position to feeder holding section 21. Then, when detachment material 24c is swung from the horizontal posture to the vertical posture, collection section 24c2 abuts on reel 70 and collects reel 70. Then, when detachment material 24c returns from the vertical posture to the horizontal posture, collection section 24c2 pulls out reel 70 from reel holding shaft 61 and holds reel 70 in the horizontal posture. In this case, setup device 10a deletes the identification information of reel 70 from the storage section of the feeder control section of feeder 60. Further, setup device 10a transmits the identification information of feeder 60 from which reel 70 has been detached to a higher-level management device. At this time, setup device 10a may transmit the identification information of detached reel 70 together with the identification information of feeder 60 to the higher-level management device.

Next, reel detachment mechanism 24 retrieves reel 70 (step S5). Specifically, first, moving table 24b moves from feeder holding section 21 to the standby position. Then, collection section 24c2 releases reel 70. Thus, released reel 70 falls into retrieval box 24d and is retrieved. When reel 70 is retrieved, the first-series control is in a standby state until the second-series control ends.

There is a possibility that feeder 60 is provided with used reel 70 in which all of carrier tape 72 has been used (step S2). In this case, in the first-series control, the control illustrated in step S3 is omitted, and the controls illustrated in step S4 and step S5 are executed. There is a possibility that feeder 60 is not provided with reel 70 (step S2). In this case, in the first-series control, the control illustrated in steps S3 to S5 is omitted.

In the second-series control, reel transfer mechanism 40 collects uppermost reel 70 of reel holding section 31 using collection section 43, and places reel 70 on placement area 22d (step S11). Then, reel transfer mechanism 40 returns collection section 43 to above reel holding section 31. When there is no applicable feeder 60, reel transfer mechanism 40 places reel 70 in temporary placement area 22e.

Next, reel attachment mechanism 22 changes the posture of reel 70 in placement area 22d (step S12). Specifically, first, attachment material 22c is changed from the upright posture to the horizontal posture, and collection section 22c2 abuts on reel 70 to collect reel 70. Then, attachment material 22c is returned from the horizontal posture to the upright posture, and collection section 22c2 changes reel 70 from the horizontal posture to the vertical posture and holds reel 70. When reel 70 in temporary placement area 22e is used, moving table 22b moves to the second end side (arrow X2 direction) in the first direction by a predetermined distance before attachment material 22c shifts from the upright posture to the horizontal posture. The second-series control is in a standby state until an end condition indicating the completion of the control of step S4 of the first-series is satisfied. This avoids interference between reel attachment mechanism 22 and reel detachment mechanism 24.

When the end condition described above is satisfied, reel attachment mechanism 22 attaches reel 70 on feeder 60 (step S13). Specifically, in a state where collection section 22c2 holds reel 70 in the vertical posture, moving table 22b moves to feeder holding section 21. Accordingly, reel 70 moves toward reel holding shaft 61 and is attached to reel holding shaft 61. The movement of moving table 22b can be performed simultaneously with the movement of moving table 24b to the standby position.

When the attachment of reel 70 ends, setup device 10a stores the identification information of reel 70 in the feeder control section of feeder 60 to which reel 70 is attached. Further, setup device 10a transmits the identification information of feeder 60 and the identification information of reel 70 provided on feeder 60 to the higher-level management device in association with each other. Moving table 22b returns to the standby position. Next, tape loading mechanism 23 loads carrier tape 72 until feed holes 72e of carrier tape 72 engage with the teeth portion of sprocket 64 (step S14).

When the first-series control and the second-series control end, feeder conveyance section 52 pulls out feeder 60 from feeder holding section 21, incorporates feeder 60 therein, moves feeder 60 to feeder accommodation section 51, and inserts incorporated feeder 60 into feeder accommodation section 51 (step S6). Thus, the setup work for one feeder 60 ends. Setup device 10a determines whether the setup work for all feeders 60 has ended (step S7). When the setup work for all feeders 60 has ended (Yes in step S7), the control by setup device 10a temporarily ends. When the setup work for all feeders 60 has not ended (No in step S7), the control by setup device 10a returns to the control illustrated in step S1, and the control described above is repeated until the setup work for all feeders 60 ends.

When the control by setup device 10a ends, for example, the worker conveys feeder accommodation section 51 accommodating feeder 60 that has been set up to the component mounter, and performs the setup change of feeder 60. When reel 70 is placed in temporary placement area 22e, when the worker accommodates feeder 60 applicable to reel 70 in feeder accommodation section 51, reel 70 becomes usable. Further, reel 70 left unused in temporary placement area 22e is returned to reel holding section 31 by reel transfer mechanism 40 and retrieve by the worker. Further, the above-described conveyance work by the worker can also be automated using a known automated guided vehicle or the like.

### 1-3. Configuration Example of Component Confirmation Device 80

In the kitting operation of setting reel 70 in feeder 60, it is necessary to set appropriate reel 70 on feeder 60. In order to confirm that appropriate reel 70 is set on feeder 60, for example, it is assumed that an identification code provided in feeder 60 and an identification code provided in reel 70 are read by a code reader, and identification information of feeder 60 and identification information of reel 70 are compared.

In this case, for example, the worker needs to read the identification code of reel 70 to be set on feeder 60, but may erroneously read the identification code of reel 70, which is detached from feeder 60. As in the embodiment, when kitting device 10 reads the identification code of feeder 60 and the identification code of reel 70, errors in the work described above are easily prevented. However, when the worker attaches the identification code to reel 70 after the delivery of reel 70, there is a possibility of attaching the wrong identification code. Further, there is a possibility that errors in reel manufacturing may occur, such as lot defects where components 91 accommodated in reel 70 differ from components 91 to be accommodated.

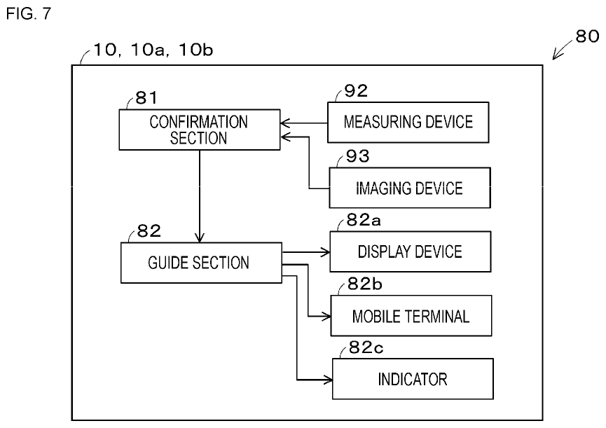

Here, in the embodiment, component confirmation device 80 is provided. Component confirmation device 80 confirms the suitability of component 91 in kitting device 10. Component confirmation device 80 includes kitting device 10 and confirmation section 81. Component confirmation device 80 may also include guide section 82. As illustrated in FIG. 7, component confirmation device 80 of the embodiment includes kitting device 10, confirmation section 81, and guide section 82. Kitting device 10 need only set reel 70 on feeder 60, and may take various configurations. For example, kitting device 10 may be setup device 10a described above or feeder unit 10b described later.

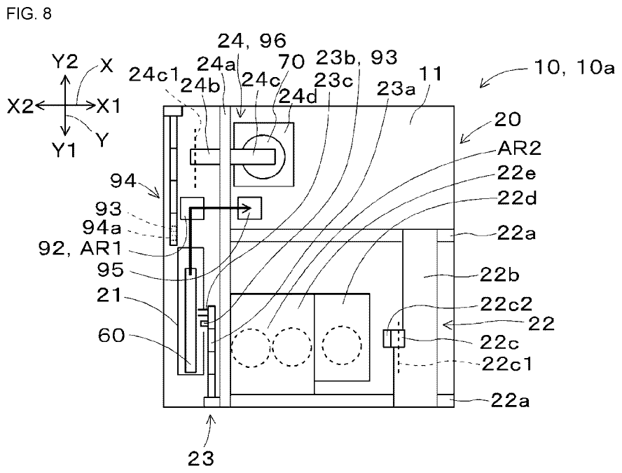

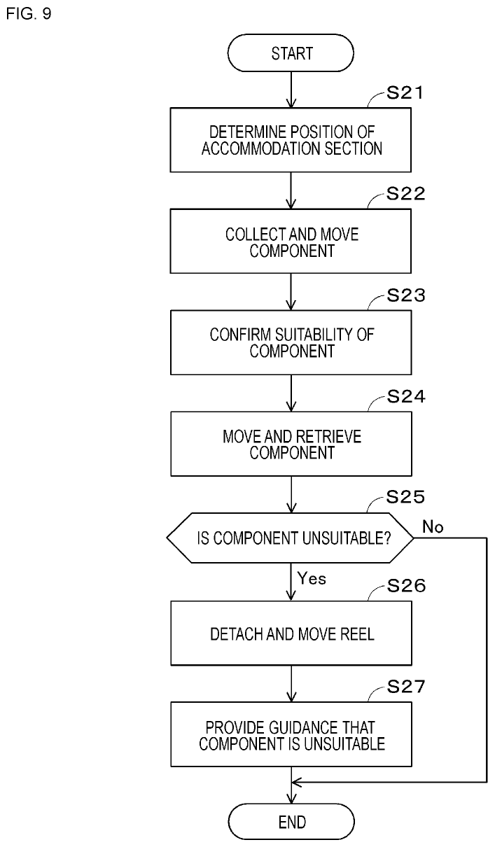

Confirmation section 81 and guide section 82 can be provided in various control devices and management devices. At least one of confirmation section 81 and guide section 82 may be formed on a cloud. As illustrated in FIG. 7, in the embodiment, confirmation section 81 and guide section 82 are provided in the control device of kitting device 10. In the embodiment, setup device 10a that is kitting device 10 includes the mechanism illustrated in FIG. 8. Further, component confirmation device 80 of the embodiment executes control in accordance with a flowchart illustrated in FIG. 9. Confirmation section 81 performs the processing described in step S23. Guide section 82 performs the processing illustrated in step S27. The mechanism illustrated in FIG. 8 performs another process illustrated in the flowchart in FIG. 9.

### 1-3-1. Confirmation Section 81

Confirmation section 81 confirms the suitability of component 91 in kitting device 10 based on the component features of component 91 accommodated in carrier tape 72 of reel 70 set on feeder 60 (step S23 illustrated in FIG. 9). Confirmation section 81 need only confirm the suitability of component 91 in kitting device 10 based on the component features (features of component 91 itself), and may take various configurations.

For example, confirmation section 81 can measure the electrical characteristics of component 91 by using measuring device 92 and confirm the suitability of component 91 based on the electrical characteristics of component 91 measured by measuring device 92. Accordingly, confirmation section 81 can confirm the suitability of component 91 based on the electrical characteristics of component 91 in the component features. Specifically, measuring device 92 measures at least one of resistance when component 91 is a resistor, inductance when component 91 is an inductor, and static capacitance when component 91 is a capacitor. As measuring device 92, a known measuring device (for example, an LCR meter) capable of measuring the above-described electrical characteristics may be used.

For example, when component 91 is a resistor, it is assumed that measuring device 92 measures the resistance of component 91. In this case, when the resistance of component 91 measured by measuring device 92 is in a predetermined range, confirmation section 81 confirms that component 91 is suitable. When the resistance of component 91 measured by measuring device 92 is not in the predetermined range, confirmation section 81 confirms that component 91 is unsuitable. What is described above similarly applies to the case where component 91 is an inductor. In addition, what is described above similarly applies to the case where component 91 is a capacitor.

The predetermined range corresponds to tolerance with respect to nominal values of the electrical characteristics, and is stored for each component 91 in a storage device such as a database. Specifically, the storage device stores identification information of reel 70, identification information of component 91 to be accommodated in reel 70, and component information related to component 91 (for example, nominal values and tolerance to electrical characteristics of component 91) in association with each other. By referring to the storage device, confirmation section 81 can acquire the component information of component 91 to be accommodated in reel 70 based on the identification information of reel 70 read from the identification code provided on reel 70, and can acquire the predetermined range described above.

When an appropriate identification code is not provided on reel 70, confirmation section 81 acquires the component information of component 91 different from component 91 actually accommodated in reel 70 from the storage device, and acquires the predetermined range described above. In this case, there is a high possibility that the electrical characteristics of component 91 measured by measuring device 92 are not in the predetermined range. Accordingly, errors such as wrong attachment of the identification code are easily detected.

When component 91 different from component 91 to be accommodated is accommodated in reel 70, confirmation section 81 acquires the component information of component 91 different from component 91 actually accommodated in reel 70 from the storage device and acquires the predetermined range described above. In this case as well, there is a high possibility that the electrical characteristics of component 91 measured by measuring device 92 are not in the predetermined range. Accordingly, errors in reel manufacturing such as lot defects are easily detected.

When measuring device 92 measures the electrical characteristics of component 91, it is necessary to change the measurement range according to component 91. When measuring device 92 measures components 91 having completely different electrical characteristics, such as when measuring the resistance of component 91 and the inductance of component 91, it is necessary to change the measurement mode (for example, a DC voltage or an AC voltage applied during measurement) according to components 91.

Similarly to the case of the predetermined range of the electrical characteristics of component 91, confirmation section 81 can acquire the measurement range and the measurement mode based on the identification information of reel 70 read from the identification code provided on reel 70 by referring to the storage device. Measuring device 92 acquires the electrical characteristics of component 91 in the measurement range and the measurement mode acquired by confirmation section 81.

When an appropriate identification code is not provided on reel 70, there is a high possibility that the measurement range and the measurement mode become incorrect. As a result, there is a high possibility that measuring device 92 cannot measure the electrical characteristics of component 91. Even if the electrical characteristics of component 91 can be measured, there is a high possibility that the electrical characteristics of component 91 measured by measuring device 92 are not in the predetermined range. In any of the above cases, confirmation section 81 can confirm that component 91 is unsuitable. What is described above similarly applies to the case where component 91 different from component 91 to be accommodated is accommodated in reel 70.

Confirmation section 81 can image component 91 by using imaging device 93 and confirm the suitability of component 91 based on an appearance image of component 91 imaged by imaging device 93. Accordingly, confirmation section 81 can confirm the suitability of component 91 based on the appearance of component 91 in the component features. Specifically, confirmation section 81 performs image processing on the appearance image to acquire component information related to component 91 attached to component 91, and confirms the suitability of component 91 based on the acquired component information. As imaging device 93, a known imaging device capable of imaging the appearance (a portion where component information can be acquired through image processing) of component 91 may be used.

For example, when component 91 is a resistor, imaging device 93 images an area (for example, sequence 103) including characters, numerals, symbols, and the like attached to component 91 to acquire an appearance image of component 91. In this case, confirmation section 81 can recognize sequence 103 by performing image processing on the appearance image, and can acquire the electrical characteristics (10 kΩ (=10×10³ Ω)) of component 91 in the component information. In addition, confirmation section 81 may also be able to acquire the outer dimensions of component 91, the tolerance (for example, ±5% in the case of the resistor of E24 series) with respect to the nominal resistance value, the manufacturer, the model, the lot number, and the like of component 91 that are included in the component information.

When the component information acquired based on the appearance image of component 91 matches the component information stored in the storage device described above, confirmation section 81 confirms that component 91 is suitable. When the component information acquired based on the appearance image of component 91 does not match the component information stored in the storage device described above, confirmation section 81 confirms that component 91 is unsuitable. What is described above similarly applies to the case where component 91 is an inductor. In addition, what is described above similarly applies to the case where component 91 is a capacitor.

As described above, the component information stored in the storage device can be acquired based on the identification information of reel 70 read from the identification code provided on reel 70. When an appropriate identification code is not provided on reel 70, confirmation section 81 acquires the component information of component 91 different from component 91 actually accommodated in reel 70 from the storage device. In this case, there is a high possibility that the component information acquired based on the appearance image of component 91 does not match the component information stored in the storage device. Accordingly, errors such as wrong attachment of the identification code are easily detected.

When component 91 different from component 91 to be accommodated is accommodated in reel 70, confirmation section 81 acquires the component information of component 91 different from component 91 actually accommodated in reel 70 from the storage device. In this case as well, there is a high possibility that the component information acquired based on the appearance image of component 91 does not match the component information stored in the storage device. Accordingly, errors in reel manufacturing such as lot defects are easily detected.

Confirmation section 81 can also confirm both the suitability of component 91 using measuring device 92 and the suitability of component 91 using imaging device 93. In this case, confirmation section 81 can confirm the suitability of component 91 by multiple confirmation methods. Specifically, when component 91 is confirmed to be suitable by confirming component 91 using measuring device 92 and component 91 is confirmed to be suitable by confirming component 91 using imaging device 93, confirmation section 81 confirms that component 91 is suitable. Further, the configurations of confirmation section 81 described above can be optionally combined, and applied in any embodiment described in the present description.

### 1-3-2. Application Example of Confirmation Section 81 to Setup Device 10a

Setup device 10a automatically sets reel 70 on feeder 60 so that component 91 can be supplied from feeder 60. Setup device 10a may have any of the configurations described above.

In order for confirmation section 81 to confirm the suitability of component 91 based on the component features (features of component 91 itself), it is necessary for measuring device 92 to be in a state capable of measuring the electrical characteristics of component 91. Similarly, in order for confirmation section 81 to confirm the suitability of component 91 based on the component features (features of component 91 itself), it is necessary for imaging device 93 to be in a state capable of imaging the appearance image of component 91. In addition, for example, there are cases where it is difficult for measuring device 92 to measure the electrical characteristics of component 91 in a state where component 91 is accommodated in carrier tape 72. Similarly, there are cases where it is difficult for imaging device 93 to image an appearance image from which component information can be acquired in a state where component 91 is accommodated in carrier tape 72.

Setup device 10a may include tape loading mechanism 23 and component movement mechanism 94. For example, as illustrated in FIG. 4, carrier tape 72 includes empty accommodation sections 72d1. Empty accommodation sections 72d1 are accommodation sections 72d capable of accommodating a predetermined number (for example, three in the drawing) of components 91 from the tip end side of carrier tape 72, and are accommodation sections 72d in which component 91 is not accommodated. When loading carrier tape 72, tape loading mechanism 23 conveys carrier tape 72 by the number of empty accommodation sections 72d1, and positions leading accommodation section 72d accommodating component 91 at a predetermined position (step S21 illustrated in FIG. 9). Specifically, tape loading mechanism 23 positions leading accommodation section 72d accommodating component 91 at a predetermined position (for example, a predetermined position on the upstream side of collection position 63) with respect to collection position 63.

Component movement mechanism 94 collects components 91 from accommodation sections 72d, where components 91 positioned by tape loading mechanism 23 are accommodated, and moves components 91 to component confirmation area AR1 in which the suitability of components 91 is confirmed (step S22 illustrated in FIG. 9). Component movement mechanism 94 need only collect components 91 from accommodation sections 72d and move to component confirmation area AR1 and may take various configurations. For example, an articulated robot may be used as component movement mechanism 94. Component movement mechanism 94 may include an XY table (a moving mechanism movable in a first direction (arrow X direction) and a second direction (arrow Y direction)) and a lifting and lowering mechanism.

Component movement mechanism 94 includes collection section 94a. Collection section 94a need only collect components 91, and may take various configurations. For example, a pickup mechanism or the like that picks up components 91 using negative pressure may be used as collection section 94a. In this case, component movement mechanism 94 collects components 91 from accommodation sections 72d, where components 91 positioned by tape loading mechanism 23 are accommodated, by picking up components 91 with collection section 94a, and moves components 91 to component confirmation area AR1.

Component confirmation area AR1 can be provided in any area of setup device 10a, but it is preferable to be provided in the vicinity of feeder 60 held by feeder holding section 21. As illustrated in FIG. 8, component confirmation area AR1 of the embodiment is provided on the second end side (arrow Y2 direction) in the second direction with respect to feeder 60 held by feeder holding section 21 and on the first end side (arrow Y1 direction) in the second direction with respect to moving table 24b of reel detachment mechanism 24.

Further, measuring device 92 is provided in component confirmation area AR1. Components 91 collected by component movement mechanism 94 are moved onto the measuring terminal of measuring device 92. Accordingly, measuring device 92 can measure the electrical characteristics of component 91 by component 91 alone. Component movement mechanism 94 can also include imaging device 93. Components 91 collected by component movement mechanism 94 are moved to component confirmation area AR1, so that an appearance image can be imaged by imaging device 93 provided in component movement mechanism 94.

When measuring device 92 can measure the electrical characteristics of component 91 in a state where component 91 is accommodated in carrier tape 72, setup device 10a can omit component movement mechanism 94. In this case, measuring device 92 can bring the measuring terminal into contact with the electrode section of component 91 using finger 23c of tape loading mechanism 23. Similarly, when imaging device 93 can image an appearance image from which component information can be acquired in a state where component 91 is accommodated in carrier tape 72, setup device 10a can omit component movement mechanism 94. In this case, camera 23b of tape loading mechanism 23 may be used as imaging device 93.

As described above, when the electrical characteristics of component 91 are measured by measuring device 92, confirmation section 81 confirms the suitability of component 91 based on the electrical characteristics of component 91 measured by measuring device 92 (step S23 illustrated in FIG. 9). When the appearance image of component 91 is imaged by imaging device 93, confirmation section 81 confirms the suitability of component 91 based on the appearance image of component 91 imaged by imaging device 93 (step S23 illustrated in FIG. 9).

For example, there is a possibility that foreign matter such as dust is attached to component 91 whose suitability is confirmed. Therefore, it is not preferable to return component 91 whose suitability is confirmed to accommodation section 72d of carrier tape 72. Setup device 10a may include component retrieval box 95 for retrieving components 91. Component retrieval box 95 need only retrieve components 91 and may take various configurations. Component retrieval box 95 of the embodiment is formed in a box shape opening upward. In a configuration in which setup device 10a includes component retrieval box 95, component movement mechanism 94 moves components 91 whose suitability is confirmed to component retrieval box 95.

Accordingly, components 91 whose suitability is confirmed are moved from component confirmation area AR1 and retrieved in component retrieval box 95 (step S24 illustrated in FIG. 9). A thick line arrow illustrated in FIG. 8 indicates an example of a movement path of component 91 from when component 91 is collected by component movement mechanism 94 to when component 91 is retrieved in component retrieval box 95. Component retrieval box 95 can be provided in any area of setup device 10a, but it is preferable to be provided in the vicinity of component confirmation area AR1. As illustrated in FIG. 8, in the embodiment, component retrieval box 95 is provided on the first end side (arrow X1 direction) in the first direction with respect to component confirmation area AR1 and on the first end side (arrow Y1 direction) in the second direction with respect to retrieval box 24d of reel detachment mechanism 24.

It is necessary to detach reel 70 accommodating component 91, for which component 91 is confirmed to be unsuitable by confirmation section 81, from feeder 60 to prevent reel 70 from being used in production. Setup device 10a may include reel movement mechanism 96. When component 91 is confirmed to be unsuitable by confirmation section 81, reel movement mechanism 96 detaches reel 70 accommodating component 91 from feeder 60 and moves reel 70 to reel storage area AR2 (Yes in step S25 and step S26 illustrated in FIG. 9).

Reel movement mechanism 96 need only detach reel 70 from feeder 60 and move reel 70 to reel storage area AR2, and may take various configurations. For example, reel detachment mechanism 24 may be used as reel movement mechanism 96. As described above, reel detachment mechanism 24 detaches reel 70 from feeder 60 and moves reel 70 to retrieval box 24d.

When reel storage area AR2 is provided in retrieval box 24d, reel 70 accommodating suitable component 91 and reel 70 accommodating unsuitable component 91 coexist in retrieval box 24d. Reel storage area AR2 may be provided in an area different from retrieval box 24d. As illustrated in FIG. 8, reel storage area AR2 of the embodiment is provided in an area between tape loading mechanism 23 and temporary placement area 22e in the first direction (arrow X direction).

When component 91 is confirmed to be suitable by confirmation section 81 (No in step S25 illustrated in FIG. 9), the processing illustrated in step S26 and step S27 to be described later is not executed, and the control by component confirmation device 80 is temporarily ended. Setup device 10a of the embodiment includes tape loading mechanism 23, component movement mechanism 94, component retrieval box 95, and reel movement mechanism 96 in relation to component confirmation device 80. Setup device 10a may have a configuration that includes tape loading mechanism 23, component movement mechanism 94, and reel movement mechanism 96 in relation to component confirmation device 80. Setup device 10a may have a configuration that includes only reel movement mechanism 96 in relation to component confirmation device 80.

### 1-3-3. Application Example of Confirmation Section 81 to Feeder Unit 10b

In feeder unit 10b, reel 70 is set on feeder 60 by a worker. Feeder unit 10b need only hold feeder 60 on which reel 70 is set, and may take various configurations.

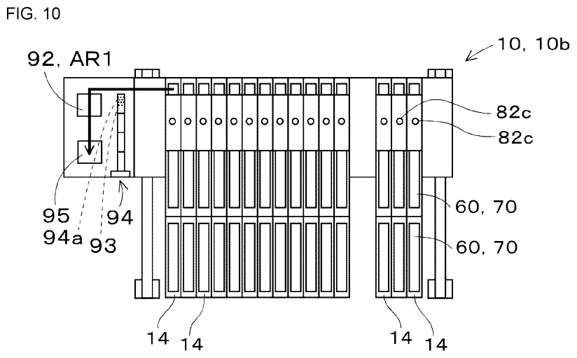

For example, feeder unit 10b illustrated in FIG. 10 includes multiple slots 14. Each of multiple slots 14 is formed similarly to slot 21b of feeder holding section 21 of setup device 10a, and can hold feeder 60 on which reel 70 is set by the worker. Feeder unit 10b may include at least one of measuring device 92 and imaging device 93 described above in setup device 10a. Feeder unit 10b illustrated in FIG. 10 includes both measuring device 92 and imaging device 93.

Further, feeder unit 10b may include at least one of component movement mechanism 94 and component retrieval box 95 described above in setup device 10a. Feeder unit 10b illustrated in FIG. 10 includes both component movement mechanism 94 and component retrieval box 95. As described above, feeder unit 10b includes a mechanism similar to that of setup device 10a in relation to component confirmation device 80, and can obtain an effect similar to the effect described above in relation to component confirmation device 80.

In feeder unit 10b, reel 70 is detached from feeder 60 by the worker. Therefore, feeder unit 10b illustrated in FIG. 10 does not include reel movement mechanism 96 described above in setup device 10a. However, feeder unit 10b may include a mechanism corresponding to reel movement mechanism 96.

### 1-3-4: Guide Section 82

When component 91 is confirmed to be unsuitable by confirmation section 81, guide section 82 provides guidance that component 91 is unsuitable (Yes in step S25 and step S27 illustrated in FIG. 9). Guide section 82 need only provide guidance that component 91 is unsuitable, and may take various configurations. Guide section 82 can be applied to various kitting devices 10. For example, guide section 82 can be applied when kitting device 10 is in the configuration of setup device 10a, and can also be applied when kitting device 10 is in the configuration of feeder unit 10b.

For example, as illustrated in FIG. 7, setup device 10a includes display device 82a. Guide section 82 can display or provide voice guidance that component 91 is unsuitable on display device 82a when component 91 is confirmed to be unsuitable by confirmation section 81. In addition, guide section 82 can provide guidance that component 91 is unsuitable through display, voice guidance, or vibration on mobile terminal 82b carried by the worker when component 91 is confirmed to be unsuitable by confirmation section 81. Further, guide section 82 can also provide guidance (for example, location of reel 70, identification information, and the like) related to reel 70 in which unsuitable component 91 is accommodated.

As illustrated in FIG. 10, feeder unit 10b includes indicator 82c. Indicator 82c is provided for each slot 14. Guide section 82 can provide guidance that component 91 is unsuitable on indicator 82c when component 91 is confirmed to be unsuitable by confirmation section 81. Specifically, guide section 82 turns on, changes the display color of, or flashes indicator 82c provided in slot 14 holding feeder 60 to which reel 70 accommodating unsuitable component 91 is attached. Accordingly, the worker recognizes the presence of unsuitable component 91 and the location of reel 70 accommodating unsuitable component 91.

### 1-3-5. Configuration Example of Production Facility

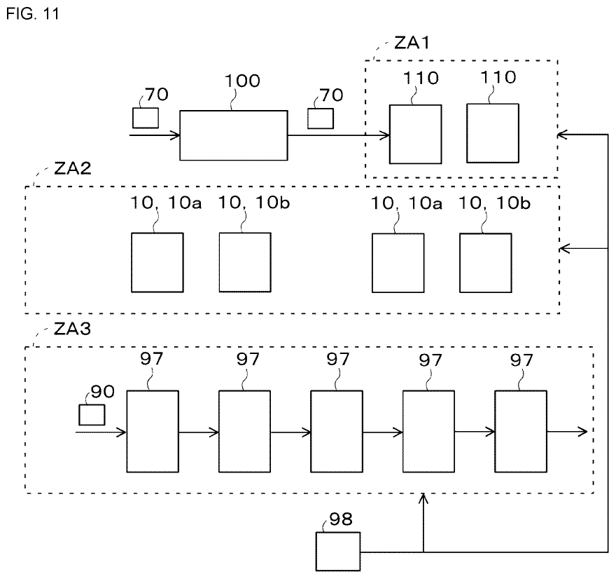

As illustrated in FIG. 11, the production facility of the embodiment includes arrival section 100, warehouse 110, kitting device 10, and component mounter 97. Reel 70 is delivered to arrival section 100, and for example, an identification code is attached to reel 70 by the worker. When the identification code is attached, reel 70 is stored in warehouse 110 and retrieved when it is required for component mounter 97. Warehouse 110 is provided in storage area ZA1. Warehouse 110 need only store reel 70, and may take various configurations. Warehouse 110 of the embodiment is an automated warehouse in which retrieval of reel 70 is automated.

As described above, in kitting device 10, reel 70 is set on feeder 60. Kitting device 10 is provided in off-line setup area ZA2. Kitting device 10 need only set reel 70 on feeder 60, and may take various configurations. The production facility of the embodiment includes both setup device 10a and feeder unit 10b. Feeder 60, on which reel 70 is set, is conveyed to component mounter 97 that mounts component 91 on board 90 when component 91 is confirmed to be suitable by confirmation section 81. Component mounter 97 is provided in production area ZA3. Reel 70 used in component mounter 97 is detached from feeder 60 in kitting device 10 and stored in warehouse 110. The conveyance of feeder 60 and reel 70 may be performed by the worker or by automated guided vehicle 98.

For example, feeder 60, on which reel 70 is set, can be conveyed by automated guided vehicle 98 to component mounter 97 that mounts component 91 on board 90 when component 91 is confirmed to be suitable by confirmation section 81. Automated guided vehicle 98 can also exchange feeder 60 in component mounter 97. The conveyance of reel 70 and feeder 60 by automated guided vehicle 98 can be applied to any configuration described above in the present description.

In the conveyance of feeder 60 by automated guided vehicle 98 described above, when feeder 60 is conveyed from kitting device 10, component 91 can be supplied to component mounter 97 without worker intervention. Therefore, component 91 confirmed suitable by confirmation section 81 can be reliably supplied to component mounter 97. When kitting device 10 is setup device 10a, the work of setting reel 70 in feeder 60 can be performed without worker intervention, which is additionally beneficial.

Confirmation section 81 confirms the suitability of component 91 in kitting device 10. In the case of confirming the suitability of component 91 in component mounter 97, measuring device 92, imaging device 93, and the like are required for each component mounter 97. In addition, when it is confirmed that component 91 is unsuitable in component mounter 97, there is a possibility that the production in component mounter 97 stops, leading to a decrease in production efficiency. By confirming the suitability of component 91 in kitting device 10 by confirmation section 81, it is possible to address the issue in advance, and it is possible to prevent a decrease in production efficiency of component mounter 97 due to the unsuitability of component 91.

### 2. Example of Effect of Embodiment

With component confirmation device 80 described above, it is possible to confirm the suitability of component 91 in kitting device 10 based on component features of component 91 accommodated in carrier tape 72 of reel 70 set on feeder 60.

### REFERENCE SIGNS LIST

10: Kitting device, 10a: setup device, 10b: feeder unit, 23: tape loading mechanism, 60: feeder, 70: reel, 72: carrier tape, 72d: accommodation section, 72d1: empty accommodation section, 80: component confirmation device, 81: confirmation section, 82: guide section, 90: board, 91: component, 92: measuring device, 93: imaging device, 94: component movement mechanism, 95: component retrieval box, 96: reel movement mechanism, 97: component mounter, 98: automated guided vehicle, AR1: component confirmation area, AR2: reel storage area

1. A component confirmation device comprising:
a kitting device configured to set a reel, on which a carrier tape accommodating a component is wound, on a feeder; and
a confirmation section configured to confirm suitability of the component in the kitting device based on component features of the component accommodated in the carrier tape of the reel set on the feeder.

2. The component confirmation device according to claim 1, wherein the confirmation section measures electrical characteristics of the component by using a measuring device, and confirms the suitability of the component based on the electrical characteristics of the component measured by the measuring device.

3. The component confirmation device according to claim 2, wherein the measuring device measures at least one of resistance when the component is a resistor, inductance when the component is an inductor, and static capacitance when the component is a capacitor.

4. The component confirmation device according to claim 1, wherein the confirmation section images the component by using an imaging device, and confirms the suitability of the component based on an appearance image of the component imaged by the imaging device.

5. The component confirmation device according to claim 4, wherein the confirmation section performs image processing on the appearance image to acquire component information related to the component attached to the component, and confirms the suitability of the component based on the acquired component information.

6. The component confirmation device according to claim 1, wherein the kitting device is a setup device configured to automatically set the reel in the feeder so that the component can be supplied from the feeder.

7. The component confirmation device according to claim 6,
wherein the setup device includes:
a tape loading mechanism configured to convey the carrier tape by the number of empty accommodation sections, which are accommodation sections configured to accommodate a predetermined number of the components from a tip end side of the carrier tape, and where the component is not accommodated, and to position a leading accommodation section accommodating the component at a predetermined position; and
a component movement mechanism configured to collect the components from the accommodation sections in which the components positioned by the tape loading mechanism are accommodated, and to move the components to a component confirmation area in which the suitability of the components is confirmed.

8. The component confirmation device according to claim 7,
wherein the setup device includes a component retrieval box configured to retrieve the components, and
the component movement mechanism moves the components whose suitability is confirmed to the component retrieval box.

9. The component confirmation device according to claim 6, wherein the setup device includes a reel movement mechanism configured to detach the reel accommodating the component from the feeder and move the reel to a reel storage area when the component is confirmed to be unsuitable by the confirmation section.

10. The component confirmation device according to claim 1, wherein the kitting device is a feeder unit in which the reel is set on the feeder by a worker.

11. The component confirmation device according to claim 1, further comprising:
a guide section configured to provide guidance that the component is unsuitable when the component is confirmed to be unsuitable by the confirmation section.

12. The component confirmation device according to claim 1, wherein the feeder, on which the reel is set, is conveyed by an automated guided vehicle to a component mounter configured to mount the component on a board when the component is confirmed to be suitable by the confirmation section.
